(19) United States
(12) Patent Application Publication
(10) Pub. No.: US 2025/0247957 A1
(43) Pub. Date: Jul. 31, 2025

(54) CIRCUIT SUBSTRATE AND METHOD FOR FABRICATING THE SAME

(71) Applicant: Industrial Technology Research Institute, Hsinchu (TW)

(72) Inventors: Chih Wei Lu, Taoyuan City (TW); Hsien-Wei Chiu, Taoyuan City (TW)

(73) Assignee: Industrial Technology Research Institute, Hsinchu (TW)

(21) Appl. No.: 19/023,360

(22) Filed: Jan. 16, 2025

Related U.S. Application Data
(60) Provisional application No. 63/626,542, filed on Jan. 30, 2024.

(30) Foreign Application Priority Data
Dec. 17, 2024 (TW) 113149164

(51) Int. Cl. H05K 1/11; H05K 1/03; H05K 3/12; H05K 3/40

(52) U.S. Cl. CPC H05K 1/115; H05K 1/0306; H05K 3/12; H05K 3/4038; H05K 2201/09563; H05K 2201/09581

(57) ABSTRACT

A circuit substrate including a glass substrate, a conductive post, and a dielectric layer is provided. The glass substrate has a through hole, the conductive post is located in the through hole, and the dielectric layer is located in the through hole, wherein the conductive post is separated from the glass substrate by the dielectric layer.

### CROSS-REFERENCE TO RELATED APPLICATION

This application claims the priority benefit of U.S. provisional application Ser. No. 63/626,542, filed on Jan. 30, 2024, and Taiwan application serial no. 113149164, filed on Dec. 17, 2024. The entirety of each of the above-mentioned patent applications is hereby incorporated by reference herein and made a part of this specification.

### TECHNICAL FIELD

The disclosure relates to a circuit substrate and a method for fabricating the same, and to a circuit substrate and a method for fabricating the same having better reliability.

### BACKGROUND

Glass packaging substrates used to carry semiconductor chips (i.e., integrated circuits) have been widely used in the packaging of semiconductor chips. Taking silicon chips as an example, glass packaging substrates have a coefficient of thermal expansion matching silicon chips, and the smooth surface of the glass packaging substrates facilitates the high-frequency application of silicon chips. In addition, glass packaging substrates have very good dimensional stability and very good thermal conductivity properties. In general, the coefficient of thermal expansion of glass packaging substrates is about five times or more that of bismaleimide triazine resin (BT) circuit substrates. Therefore, glass packaging substrates have their advantages in the field of semiconductor chip packaging. However, existing glass packaging substrates still face issues such as inability to effectively improve reliability in manufacturing.

### SUMMARY

In an embodiment of the disclosure, a circuit substrate includes a glass substrate, a conductive post, and a dielectric layer. The glass substrate has a through hole, the conductive post is located in the through hole, and the dielectric layer is located in the through hole, wherein the conductive post is separated from the glass substrate by the dielectric layer.

In another embodiment of the disclosure, a method for fabricating a circuit substrate includes the following steps. A first through hole is formed in a glass substrate. A dielectric layer is formed to cover a top surface of the glass substrate and to be filled in the first through hole. A second through hole is formed in the dielectric layer. A conductive post is formed in the second through hole.

In another embodiment of the disclosure, a method for fabricating a circuit substrate includes the following steps. A through hole is formed in a glass substrate. A conductive post is placed in the through hole of the glass substrate. A first dielectric portion is formed in the through hole of the glass substrate to fix the conductive post in the through hole.

In other embodiments of the disclosure, a method for fabricating a circuit substrate includes the following steps. A through hole is formed in a glass substrate, wherein the glass substrate has a crack located around the through hole. A conductive layer is formed in the through hole of the glass substrate to repair the crack. A first dielectric portion is formed in the through hole of the glass substrate.

### BRIEF DESCRIPTION OF THE DRAWINGS

FIG. 1 to FIG. 8 are schematic cross-sectional views of the manufacturing process of a circuit substrate according to the first embodiment of the disclosure.

FIG. 9 to FIG. 13 are schematic cross-sectional views of the manufacturing process of a circuit substrate according to the second embodiment of the disclosure.

FIG. 14 to FIG. 18 are schematic cross-sectional views of the manufacturing process of a circuit substrate according to the third embodiment of the disclosure.

### DETAILED DESCRIPTION OF DISCLOSED EMBODIMENTS

Embodiments are provided hereinafter and described in detail with reference to figures. However, the embodiments provided are not intended to limit the scope of the disclosure. In addition, the drawings are for illustration purposes and are not drawn to original scale. In order to facilitate understanding, the same elements are described with the same reference numerals in the following description. In addition, the terms “contain”, “include”, “have”, etc. used in the article are all open terms, meaning “containing but not limited to”. Furthermore, the directional terms mentioned in the article, such as “up”, “down”, etc., are used to refer to the direction of the drawings and are not used to limit the disclosure. In addition, the quantities and shapes mentioned in the specification are used to specifically illustrate the disclosure to facilitate understanding of the content thereof, but are not used to limit the disclosure.

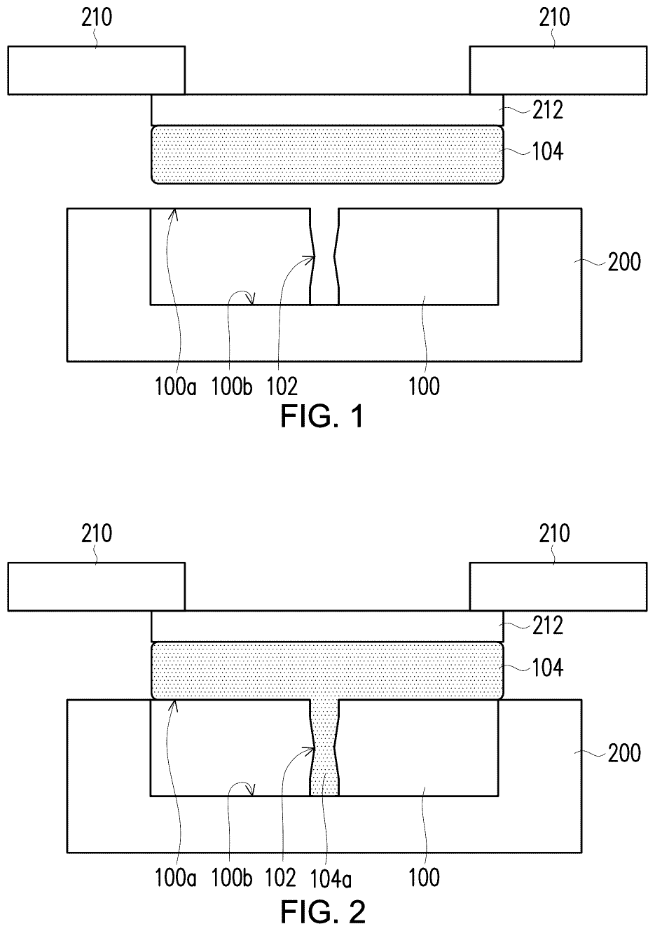

FIG. 1 to FIG. 8 are schematic cross-sectional views of the manufacturing process of a circuit substrate according to the first embodiment of the disclosure.

Referring to FIG. 1, a glass substrate 100 is provided. The glass substrate 100 has a top surface 100a, a bottom surface 100b opposite to the top surface 100a, and a through hole 102 penetrating the glass substrate 100, wherein the through hole 102 is extended from the top surface 100a of the glass substrate 100 to the bottom surface 100b of the glass substrate 100. The through hole 102 in the glass substrate 100 may be formed by a method of laser drilling. During the laser drilling process, the glass material in the glass substrate 100 irradiated by the laser beam is modified and removed, and after the laser drilling process is performed, the glass substrate 100 generates micro cracks around the through hole 102 due to the internal stress of the material in the subsequent process. If these microcracks appearing around the through hole 102 are not properly handled or repaired, the yield of the subsequent process is reduced, thereby reducing the reliability of the circuit substrate made of the glass substrate 100. In order to alleviate subsequent reliability and yield issues caused by microcracks around the through hole 102, in the present embodiment, a dielectric material 104 is adopted to be filled in the through holes 102 as a buffer material.

As shown in FIG. 1, first, the glass substrate 100 having the through hole 102 is placed in a bearing fixture 200. In the present embodiment, the bearing fixture 200 has a groove and a bearing surface located at the bottom of the groove, the groove of the bearing fixture 200 is adapted to accommodate the glass substrate 100, the depth of the groove of the bearing fixture 200 is equal to the thickness of the glass substrate 100, and the bottom surface 100b of the glass substrate 100 is rested on the bearing surface of the bearing fixture 200.

After the glass substrate 100 is placed in the bearing fixture 200, the dielectric material 104 located on a diaphragm 212 is picked up by a pick-up head 210. The pick-up head 210 may provide the dielectric material 104 located on the diaphragm 212 to above the bearing fixture 200 and the glass substrate 100. In the present embodiment, the dielectric material 104 distributed on the diaphragm 212 includes dry film, Ajinomoto Build-Up Film (ABF), epoxy resin, Taiwan Build-Up Film (TBF), etc. At this stage, the dielectric material 104 is in a semi-solidified state, and the dielectric material 104 may change the shape thereof under force. For example, the dielectric material 104 may include an organic dielectric material, and the Young's modulus of the dielectric material 104 is less than the Young's modulus of the glass substrate 100. In the present embodiment, the Young's modulus of the dielectric material 104 is approximately 8 GPa, and the Young's modulus of the glass substrate 100 is approximately 83 GPa. The dielectric material 104 may be used as a buffer layer to inhibit the phenomenon of further generating defects or microcracks to the glass substrate 100 after thermal shock.

Referring to FIG. 2, the relative positions of the pick-up head 210 and the bearing fixture 200 are changed to shorten the vertical distance between the pick-up head 210 and the bearing fixture 200, so as to squeeze the first dielectric portion 104a of the dielectric material 104 into the through hole 102 of the glass substrate 100, and the remaining portions of the dielectric material 104 cover the top surface 100a of the glass substrate 100 and the bearing fixture 200. In some embodiments, the relative position change of the pick-up head 210 and the bearing fixture 200 may be achieved by fixing the bearing fixture 200 and moving the pick-up head 210 downward. In another embodiment, the relative position change of the pick-up head 210 and the bearing fixture 200 may be achieved by fixing the pick-up head 210 and moving the bearing fixture 200 upward. In other embodiments, the relative position change of the pick-up head 210 and the bearing fixture 200 may be achieved by moving the pick-up head 210 and the bearing fixture 200 simultaneously.

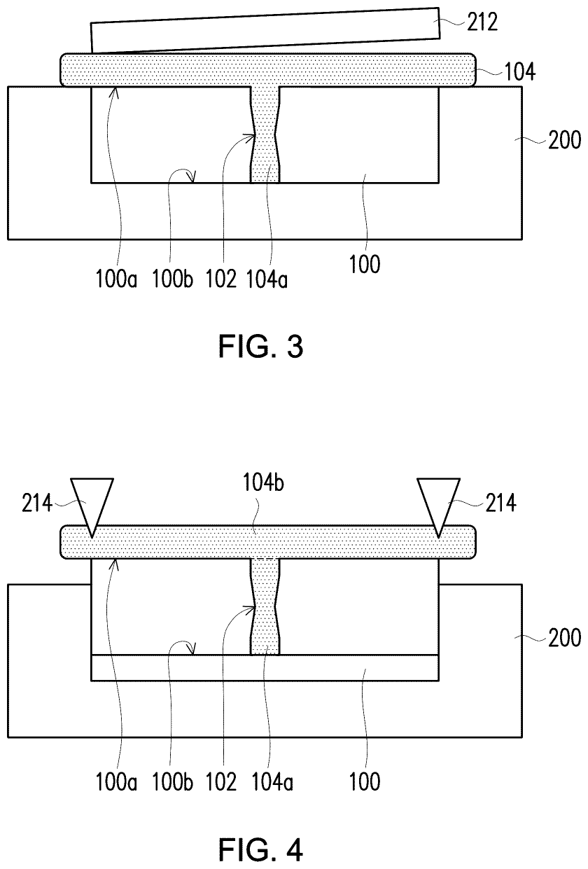

Referring to FIG. 3, after the vertical distance between the pick-up head 210 and the bearing fixture 200 is shortened to squeeze the first dielectric portion 104a of the dielectric material 104 into the through hole 102 of the glass substrate 100, the relative positions of the pick-up head 210 and the bearing fixture 200 are changed again, so that the relative positions of the pick-up head 210 and the bearing fixture 200 are restored. Next, the diaphragm 212 is peeled off from the dielectric material 104. After the diaphragm 212 is peeled off, the dielectric material 104 is subjected to a curing process.

Referring to FIG. 4, after the curing process is performed on the dielectric material 104, a trimming process is performed using a trimming fixture 214 to remove excess dielectric material 104 to form a second dielectric portion 104b on the top surface 100a of the glass substrate 100. Here, the excess dielectric material 104 refers to the dielectric material located on the bearing fixture 200. The first dielectric portion 104a and second dielectric portion 104b form a dielectric layer covering the glass substrate 100, and the first dielectric portion 104a and the second dielectric portion 104b in the dielectric layer are the same material. It may be known from FIG. 4 that, the second dielectric portion 104b covers the top surface 100a of the glass substrate 100 and the first dielectric portion 104a, and the sidewall of the second dielectric portion 104b is aligned with the sidewall of the glass substrate 100. In addition, after the cutting process of the dielectric material 104 is completed by the cutting fixture 214, the bearing fixture 200 is removed, so that the glass substrate 100 at which the dielectric layer is formed is separated from the bearing fixture 200.

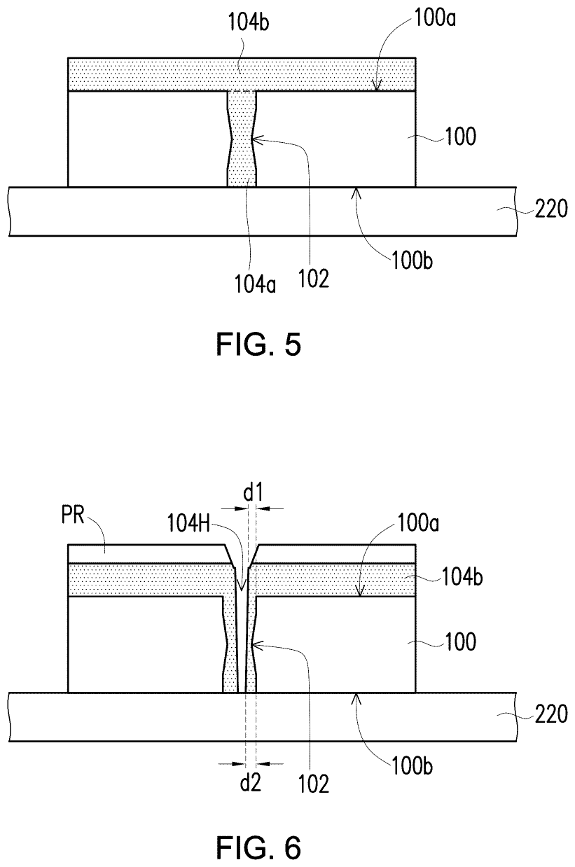

Referring to FIG. 5, after the glass substrate 100 is removed from the bearing fixture 200, the glass substrate 100 at which the first dielectric portion 104a and the second dielectric portion 104b are formed may be disposed on a stage 220 to facilitate a subsequent process. Here, the bottom surface 100b of the glass substrate 100 and the bottom surface of the first dielectric portion 104a are in contact with the stage 220.

Referring to FIG. 6, a patterning process is performed on the first dielectric portion 104a and the second dielectric portion 104b. First, a patterned photoresist layer PR is formed on the second dielectric portion 104b. The patterned photoresist layer PR has an opening to define the positions of through holes subsequently formed in the first dielectric portion 104a and the second dielectric portion 104b. Here, the opening in the patterned photoresist layer PR is located above the first dielectric portion 104a, and the lateral size of the opening in the patterned photoresist layer PR is less than the lateral size of the first dielectric portion 104a. Next, using the patterned photoresist layer PR as a mask, an etching process is performed on the first dielectric portion 104a and the second dielectric portion 104b to form a through hole 104H in the first dielectric portion 104a and the second dielectric portion 104b. Here, the through hole 104H is based on the principle that the glass substrate 100 is not exposed. In the present embodiment, the through hole 104H has a tapered sidewall, and the through hole 102 has a sidewall similar to an hourglass shape. In other words, the lateral size of the through hole 104H is gradually decreased from top to bottom, and the lateral size of the through hole 102 is first gradually decreased from top to bottom, and then gradually increased. As shown in FIG. 6, the through hole 102 has a necking portion, and the through hole 104H does not have a necking portion.

After the through hole 104H is formed, the outlines of the first dielectric portion 104a and the second dielectric portion 104b are further changed, wherein the second dielectric portion 104b defines the upper portion of the through hole 104H, the inner sidewall of the first dielectric portion 104a defines the lower portion of the through hole 104H, the outer sidewall of the first dielectric portion 104a is in contact with the glass substrate 100, and the outline of the outer sidewall of the first dielectric portion 104a is determined by the outline of the through hole 102. Since the through hole 104H has an inclined sidewall, at the level height where the top surface 100a of the glass substrate 100 is located, a lateral distance d1 is maintained between the inner sidewall and the outer sidewall of the first dielectric portion 104a, and at the level height where the bottom surface 100b of the glass substrate 100 is located, a lateral distance d2 is maintained between the inner sidewall and the outer sidewall of the first dielectric portion 104a, and the lateral distance d1 is less than the lateral distance d2. In other words, the lateral dimension (i.e., the lateral distance d1) of the first dielectric portion 104a at the level height where the top surface 100a of the glass substrate 100 is located is less than the lateral dimension (i.e., the lateral distance d2) of the first dielectric portion 104a at the level height where the bottom surface 100b of the glass substrate 100 is located.

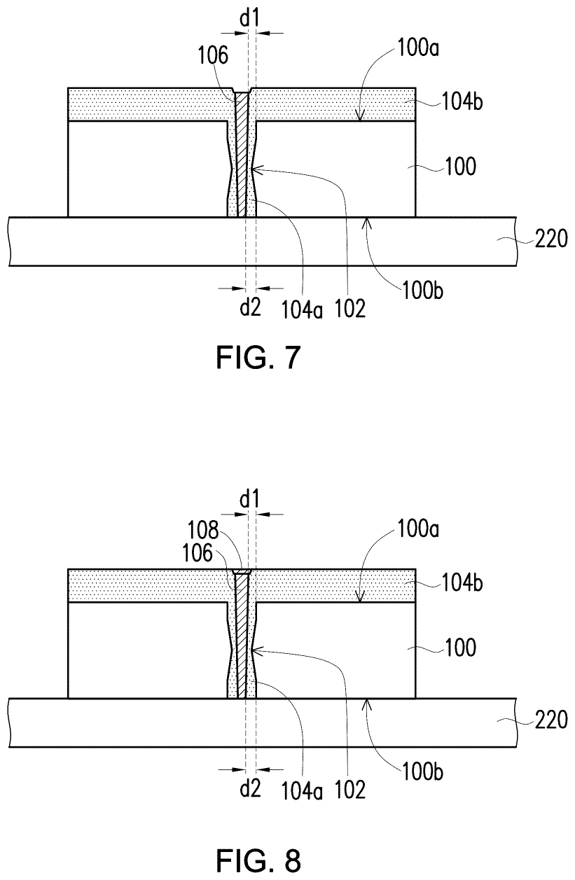

Referring to FIG. 7, a conductive post 106, such as a copper post, is formed in the through hole 104H. In the present embodiment, the Young's modulus of the conductive post 106 is about 100 GPa. Since the Young's modulus of the dielectric material 104 is less than the Young's modulus of the conductive post 106 and the glass substrate 100, the dielectric material 104 may be used as a buffer layer between the conductive post 106 and the glass substrate 100 to inhibit the phenomenon of further generating defects or microcracks to the glass substrate 100 after thermal shock. In the present embodiment, a seed layer may be formed on the first dielectric portion 104a and the second dielectric portion 104b via a sputtering process, and then a conductive material layer may be formed on the seed layer via a chemical plating or electroplating process, wherein the seed layer is conformal to the surfaces of the first dielectric portion 104a and the second dielectric portion 104b, the conductive material layer is filled in the through hole 104H, and the top surface of the conductive material layer is higher than the top surface of the second dielectric portion 104b. Then, a planarization process is performed to remove a portion of the conductive material layer and a portion of the seed layer until the top surface of the second dielectric portion 104b is exposed. In the present embodiment, the planarization process includes a chemical mechanical polishing process, a mechanical polishing process, or a combination of the above processes. As shown in FIG. 7, the top end of the conductive post 106 may be lower than the top surface of the second dielectric portion 104b. In other words, there is a recessed area above the conductive post 106 relative to the top surface of the second dielectric portion 104b.

As shown in FIG. 7, the first dielectric portion 104a of the dielectric layer is located in the through hole 102 of the glass substrate 100 to separate the conductive post 106 and the glass substrate 100. The second dielectric portion 104b covers the top surface of the first dielectric portion 104a and the top surface 100a of the glass substrate 100. In addition, the conductive post 106 has an inclined sidewall, and the conductive post 106 has a top end and a bottom end relative to the top end, wherein the width of the top end of the conductive post 106 is greater than the width of the bottom end of the conductive post 106, and the height of the conductive post 106 may be greater than the thickness of the glass substrate 100.

Referring to FIG. 8, a surface conductive layer 108 is formed in the recessed area above the conductive post 106, wherein the surface conductive layer 108 is in direct contact with and electrically connected to the conductive post 106. In the present embodiment, the surface conductive layer 108 includes a gold layer, a silver layer, a copper layer, a tin layer, a nickel layer, or a combination of the above metal layers. The surface conductive layer 108 may be filled into the recessed area above the conductive post 106 by a method such as electroplating, inkjet printing, or screen printing. As shown in FIG. 8, the top surface of surface conductive layer 108 may be flush with the top surface of second dielectric portion 104b. In other embodiments, the top surface of surface conductive layer 108 may be slightly higher or lower than the top surface of second dielectric portion 104b.

After completing the process steps described in FIG. 1 to FIG. 8, a redistribution circuit layer (not shown) electrically connected to the conductive post 106 and the surface conductive layer 108 may be further formed on at least one surface 100a or 100b of the glass substrate 100 via build-up or lamination. However, in the present embodiment, the type and the quantity of redistribution circuit layer formed on the glass substrate 100 are not limited.

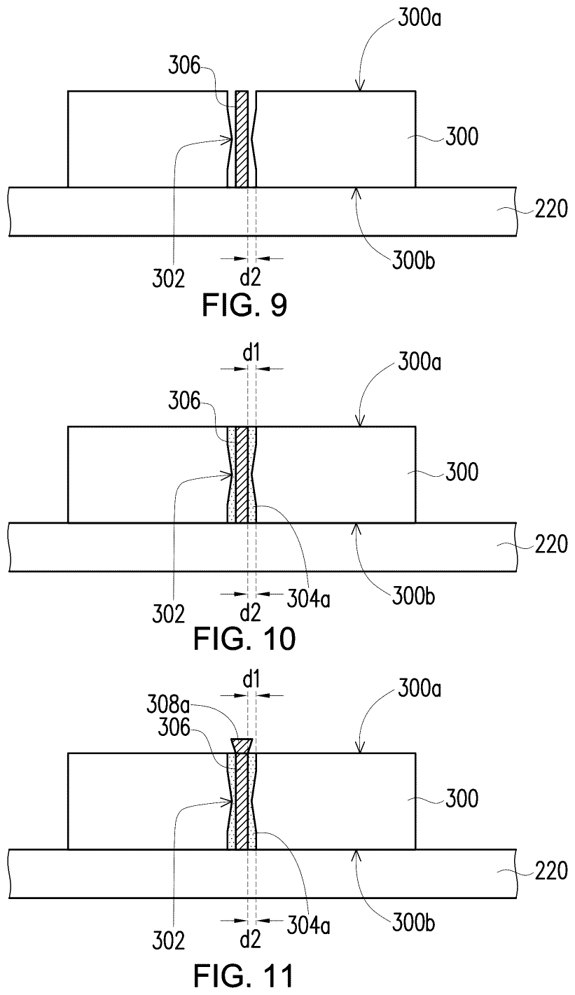

FIG. 9 to FIG. 13 are schematic cross-sectional views of the manufacturing process of a circuit substrate according to the second embodiment of the disclosure.

Referring to FIG. 9, a glass substrate 300 is provided. The glass substrate 300 has a top surface 300a, a bottom surface 100b opposite to the top surface 300a, and a through hole 302 penetrating the glass substrate 300, wherein the through hole 302 is extended from the top surface 300a of the glass substrate 300 to the bottom surface 300b of the glass substrate 300. The glass substrate 300 at which the through hole 302 is formed may be disposed on the stage 220. The through hole 302 in the glass substrate 300 may be formed by a method of laser drilling. During the laser drilling process, the glass material in the glass substrate 300 irradiated by the laser beam is modified and removed, and after the laser drilling process is performed, the glass substrate 300 generates microcracks around the through hole 302 due to internal stress of the material. If these microcracks appearing around the through hole 302 are not properly handled or repaired, the yield of the subsequent process is reduced, thereby reducing the reliability of the glass substrate 300. As shown in FIG. 9, the through hole 302 of the glass substrate 300 has a sidewall similar to an hourglass shape. In other words, the through hole 302 has a necking portion.

Next, a conductive post 306 is provided, and the conductive post 306 is placed in the through hole 302. The conductive post 306 may be a prefabricated copper post, and the diameters of prefabricated copper posts are between about 20 microns to about 50 microns. The conductive post 306 has a top end, a bottom end opposite to the top end, and a sidewall connected between the top end and the bottom end, wherein the sidewall of the conductive post 306 is perpendicular to the top end and the bottom end of the conductive post 306. In other words, the top end and the bottom end of the conductive post 306 have the same lateral dimensions. The conductive post 306 may be placed on the stage 220 exposed by the through hole 302, and the height of the conductive post 306 is equal to the thickness of the glass substrate 300. In other embodiments, the height of the conductive post 306 is less than the thickness of the glass substrate 300, and the difference between the height of the conductive post 306 and the thickness of the glass substrate 300 is within 1 micron. In this step, the conductive post 306 is not in contact with the glass substrate 300 due to being supported by the stage 220. In the present embodiment, the Young's modulus of the conductive post 306 is about 100 GPa, and the Young's modulus of the glass substrate 300 is about 83 GPa. Therefore, a buffer material is needed between the conductive post 306 and the glass substrate 300 to prevent the phenomenon of generating defects or microcracks to the glass substrate 300 after thermal shock.

Please refer to FIG. 10, after the conductive post 306 is placed, a first dielectric portion 304a covering the conductive post 306 is formed in the through hole 302 in a manner similar to FIG. 1 to FIG. 3 to fix the conductive post 306 in the through hole 302. The first dielectric portion 304a is located in the through hole 302 to separate the conductive post 306 and the glass substrate 300. In the present embodiment, the first dielectric portion 304a includes dry film, Ajinomoto build-up film (ABF), epoxy resin, Taiwan build-up film (TBF), etc. Here, since the conductive post 306 has a vertical sidewall, at the level height where the top surface 300a of the glass substrate 300 is located, a lateral distance d1 is maintained between the inner sidewall and the outer sidewall of the first dielectric portion 304a, and at the level height where the bottom surface 300b of the glass substrate 300 is located, a lateral distance d2 is maintained between the inner sidewall and the outer sidewall of the first dielectric portion 304a, and the lateral distance d1 is equal to the lateral distance d2. In other words, the lateral dimension (i.e., the lateral distance d1) of the first dielectric portion 304a at the level height where the top surface 300a of the glass substrate 300 is located is equal to the lateral dimension (i.e., the lateral distance d2) of the first dielectric portion 304a at the level height where the bottom surface 300b of the glass substrate 300 is located.

As shown in FIG. 10, the top surface of the first dielectric portion 304a is flush with the top surface 300a of the glass substrate 300, and the bottom surface of the first dielectric portion 304a is flush with the bottom surface 300b of the glass substrate 300. Furthermore, the top surface of the conductive post 306 is flush with the top surface 300a of the glass substrate 300 and the top surface of the first dielectric portion 304a, and the bottom surface of the conductive post 306 is flush with the bottom surface 300b of the glass substrate 300 and the bottom surface of the first dielectric portion 304a. In order to alleviate subsequent issues caused by microcracks around the through hole 302, in the present embodiment, the first dielectric portion 304a is adopted to be filled between (i.e., the through hole 302) the glass substrate 300 and the conductive post 306 to reduce the probability of generating microcracks around the through hole 302.

Referring to FIG. 11, after the first dielectric portion 304a is formed, the manufacture of a surface conductive layer 308a may be performed, wherein the surface conductive layer 308a is in direct contact with and electrically connected to the top end of the conductive post 306. In the present embodiment, the surface conductive layer 308a includes a gold layer, a silver layer, a copper layer, a tin layer, a nickel layer, or a combination of the above metal layers. The surface conductive layer 308a may be formed on the top end of the conductive post 306 by a method such as electroplating, inkjet printing, or screen printing. As shown in FIG. 11, the surface conductive layer 308a is protruded beyond the top surface 300a of the glass substrate 300.

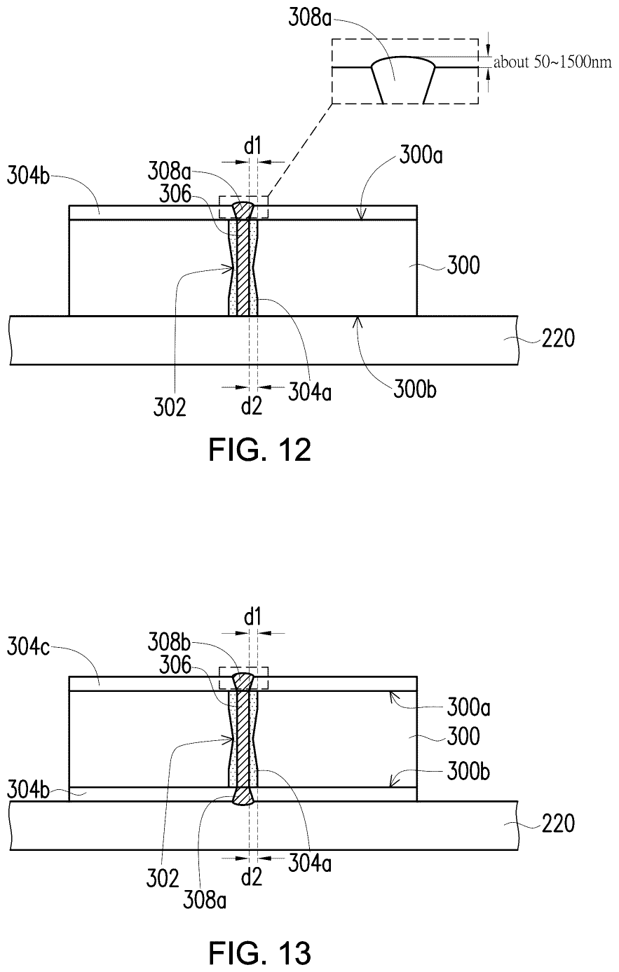

Referring to FIG. 12, a second dielectric portion 304b covering the surface conductive layer 308a is formed on the first dielectric portion 304a and the top surface 300a of the glass substrate 300 in a manner similar to that of FIG. 1 to FIG. 3. In the present embodiment, the material of the second dielectric portion 304a is the same as or different from the material of the first dielectric portion 304a, and the second dielectric portion 304a includes dry film, Ajinomoto build-up film (ABF), epoxy resin, Taiwan build-up film (TBF), etc. As shown in FIG. 12, the surface conductive layer 308a may be protruded beyond the top surface of the second dielectric portion 304b. Compared to the top surface of the second dielectric portion 304b, the surface conductive layer 308a is protruded by approximately 50 nanometers to 1500 nanometers. The top surface of the conductive post 306 is higher than the top surface of the second dielectric portion 304b.

Referring to FIG. 13, after the second dielectric portion 304b is formed, the glass substrate 300 may be turned over on the stage 220 so that the bottom surface 300b of the glass substrate 300 faces upward, and the manufacture of the surface conductive layer 308b is performed, wherein the surface conductive layer 308b is in direct contact with and electrically connected to the bottom end of the conductive post 306. In the present embodiment, the surface conductive layer 308b includes a gold layer, a silver layer, a copper layer, a tin layer, a nickel layer, or a combination of the above metal layers. The surface conductive layer 308b may be formed on the bottom end of the conductive post 306 by a method such as electroplating, inkjet printing, or screen printing. As shown in FIG. 13, the surface conductive layer 308b is protruded beyond the bottom surface 300b of the glass substrate 300.

Next, a third dielectric portion 304c covering the surface conductive layer 308b is formed on the first dielectric portion 304a and the top surface 300b of the glass substrate 300 in a manner similar to that of FIG. 1 to FIG. 3. In the present embodiment, the material of the third dielectric portion 304c is the same as or different from the material of the second dielectric portion 304b, and the material of the third dielectric portion 304c is the same as or different from the material of the first dielectric portion 304a, and the third dielectric portion 304c includes dry film, Ajinomoto build-up film (ABF), epoxy resin, Taiwan build-up film membrane (TBF), etc. As shown in FIG. 13, the surface conductive layer 308b may be protruded beyond the bottom surface of the third dielectric portion 304c. Compared to the bottom surface of the third dielectric portion 304c, the surface conductive layer 308b is protruded by approximately 50 nanometers to 1500 nanometers.

In the present embodiment, the process steps in FIG. 11 to FIG. 13 are optional process steps, and the process steps in FIG. 11 to FIG. 13 do not need to be performed, or the process steps in FIG. 11 to FIG. 12 may be performed, but the process steps in FIG. 13 may be not performed.

After completing the process steps described in FIG. 9 to FIG. 13, a redistribution circuit layer (not shown) electrically connected to the conductive post 306, the surface conductive layer 308a, and the surface conductive layer 308b may be further formed on at least one surface 300a or 300b of the glass substrate 300 via build-up or lamination. However, in the present embodiment, the type and the quantity of redistribution circuit layer formed on the glass substrate 300 are not limited.

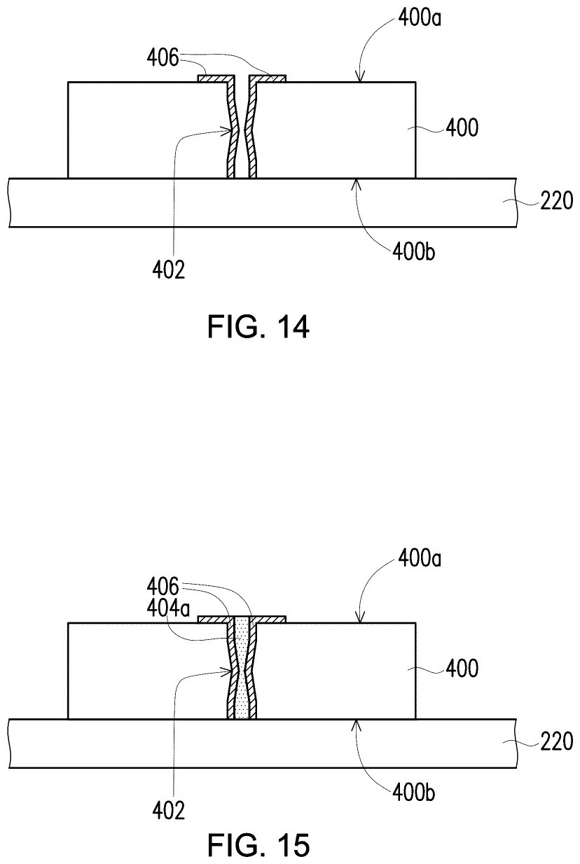

FIG. 14 to FIG. 18 are schematic cross-sectional views of the manufacturing process of a circuit substrate according to the third embodiment of the disclosure.

Referring to FIG. 14, a glass substrate 400 is provided. The glass substrate 400 has a top surface 400a, a bottom surface 400b opposite to the top surface 400a, and a through hole 402 penetrating the glass substrate 400, wherein the through hole 402 is extended from the top surface 400a of the glass substrate 400 to the bottom surface 400b of the glass substrate 400. The glass substrate 400 at which the through hole 402 is formed may be disposed on the stage 220. The through hole 402 in the glass substrate 400 may be formed by a method of laser drilling. During the laser drilling process, the glass material in the glass substrate 400 irradiated by the laser beam is modified and removed, and after the laser drilling process is performed, the glass substrate 400 generates microcracks around the through hole 402 due to internal stress of the material. If these microcracks appearing around the through hole 402 are not properly handled or repaired, the yield of the subsequent process is reduced, thereby reducing the reliability of the glass substrate 400. In order to alleviate subsequent issues caused by microcracks around the through hole 402, in the present embodiment, a conductive layer 406 is adopted to repair the microcracks around the through hole 402. As shown in FIG. 14, the through hole 402 of the glass substrate 400 has a sidewall similar to an hourglass shape. In other words, the through hole 402 has a necking portion. Moreover, the conductive layer 406 is conformal to the sidewall of the through hole 402. In addition to covering the sidewall of the through hole 402, the conductive layer 406 further covers a portion of the top surface 400a of the glass substrate 400.

In the present embodiment, in the conductive layer 406, a conductive material may be deposited on the sidewall of the through hole 402 and the top surface 400a of the glass substrate 400 via an electroless plating process. Then, a patterning process (e.g., etching process) is performed on the conductive material to remove a portion of the conductive material located on the top surface 400a, thereby completing the manufacture of the conductive layer 406.

Referring to FIG. 15, after the manufacture of the conductive layer 406 is completed, a first dielectric portion 404a in contact with the conductive layer 406 is filled in the through hole 402 in a manner similar to FIG. 1 to FIG. 3. The first dielectric portion 404a is located in the through hole 402 and separated from the glass substrate 400 by the conductive layer 406. In the present embodiment, the first dielectric portion 404a includes dry film, Ajinomoto build-up film (ABF), epoxy resin, Taiwan build-up film (TBF), etc.

As shown in FIG. 15, the top surface of the first dielectric portion 404a is flush with the top surface of the conductive layer 406 and slightly higher than the top surface 400a of the glass substrate 400, and the bottom surface of the first dielectric portion 404a is flush with the bottom end of the conductive layer 406 and the bottom surface 400b of the glass substrate 400.

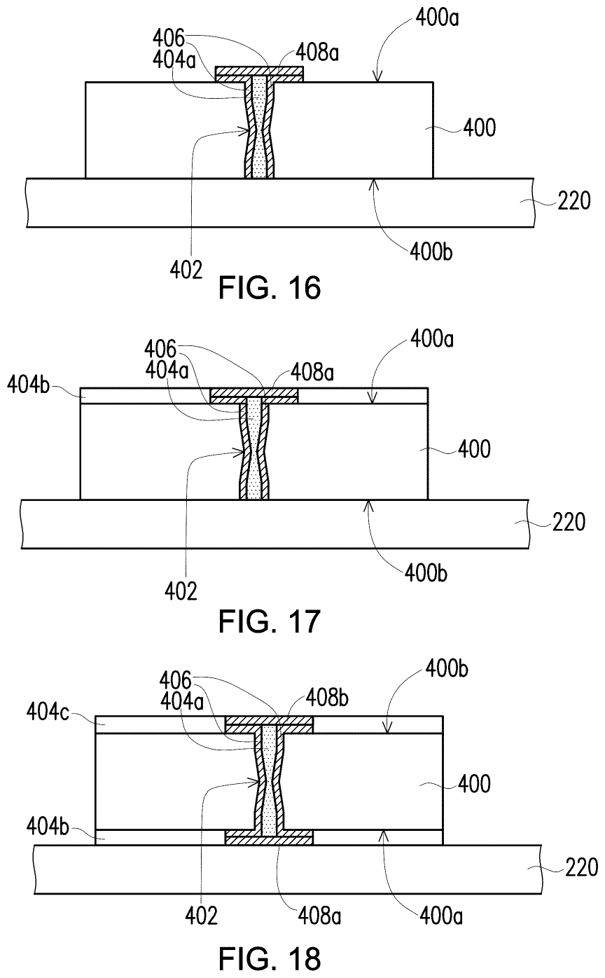

Referring to FIG. 16, after the first dielectric portion 404a is formed, the manufacture of the surface conductive layer 408a may be performed, wherein the surface conductive layer 408a is in direct contact with the top surface of the conductive layer 406 and the top surface of the first dielectric portion 404a, and the surface conductive layer 408a is electrically connected to the conductive layer 406. In the present embodiment, the surface conductive layer 408a includes a gold layer, a silver layer, a copper layer, a tin layer, a nickel layer, or a combination of the above metal layers. The surface conductive layer 408a may be formed on the top surface of the conductive layer 406 by a method such as electroplating, inkjet printing, or screen printing. As shown in FIG. 16, the surface conductive layer 408a is protruded beyond the top surface 400a of the glass substrate 400.

Referring to FIG. 17, a second dielectric portion 404b covering the surface conductive layer 408a is formed on the first dielectric portion 404a and the top surface 400a of the glass substrate 400 in a manner similar to that of FIG. 1 to FIG. 3. Next, a thinning or planarization process is performed on the second dielectric portion 404b to remove a portion of the second dielectric portion 404b until the surface conductive layer 408a is exposed. In the present embodiment, the material of the second dielectric portion 404b is the same as or different from the material of the first dielectric portion 404a, and the second dielectric portion 404b includes dry film, Ajinomoto build-up film (ABF), epoxy resin, Taiwan build-up film (TBF), etc. As shown in FIG. 17, the surface conductive layer 408a may be protruded beyond the top surface of the second dielectric portion 404b. Compared to the top surface of the second dielectric portion 404b, the surface conductive layer 408a is protruded by approximately 50 nanometers to 1500 nanometers.

Referring to FIG. 18, after the second dielectric portion 404b is formed, the glass substrate 400 may be turned over on the stage 220 so that the bottom surface 400b of the glass substrate 400 faces upward, and the manufacture of the surface conductive layer 408b is performed, wherein the surface conductive layer 408b is in direct contact with and electrically connected to the bottom end of the conductive layer 406. In the present embodiment, the surface conductive layer 408b includes a gold layer, a silver layer, a copper layer, a tin layer, a nickel layer, or a combination of the above metal layers. The surface conductive layer 408b may be formed on the bottom end of the conductive layer 406 by a method such as electroplating, inkjet printing, or screen printing. As shown in FIG. 18, the surface conductive layer 408b is protruded beyond the bottom surface 400b of the glass substrate 400.

Next, a third dielectric portion 404c covering the surface conductive layer 408b is formed on the bottom surface 400b of the glass substrate 400 in a manner similar to that of FIG. 1 to FIG. 3. Next, a thinning or planarization process is performed on the third dielectric portion 404c to remove a portion of the third dielectric portion 404c until the surface conductive layer 408b is exposed. In the present embodiment, the material of the third dielectric portion 404c is the same as or different from the material of the second dielectric portion 404b, and the material of the third dielectric portion 404c is the same as or different from the material of the first dielectric portion 404a, and the third dielectric portion 404c includes dry film, Ajinomoto build-up film (ABF), epoxy resin, Taiwan build-up film membrane (TBF), etc. As shown in FIG. 18, the surface of the surface conductive layer 408b may be flush with the surface of the third dielectric portion 404c. In other embodiments not shown, the surface conductive layer 408b may be protruded beyond the surface of the third dielectric portion 404c, and compared to the top surface of the third dielectric portion 404c, the surface conductive layer 408b is protruded by about 50 nanometers to 1500 nanometers.

In the present embodiment, the process steps in FIG. 16 to FIG. 18 are optional process steps, and the process steps in FIG. 16 to FIG. 18 do not need to be performed, or the process steps in FIG. 16 to FIG. 17 may be performed, but the process steps in FIG. 18 may be not performed.

After completing the process steps described in FIG. 14 to FIG. 18, a redistribution circuit layer (not shown) electrically connected to the conductive layer 406, the surface conductive layer 408a, and the surface conductive layer 408b may be further formed on at least one surface 400a or 400b of the glass substrate 400 via build-up or lamination. However, in the present embodiment, the type and the quantity of redistribution circuit layers formed on the glass substrate 400 are not limited.

In the above embodiments of the disclosure, the issue of microcracks of the glass substrate around the through hole may be effectively alleviated. Therefore, the reliability of the circuit substrate formed by the glass substrate may also be improved to a certain extent.

It will be apparent to those skilled in the art that various modifications and variations may be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A circuit substrate, comprising:
a glass substrate having a through hole;
a conductive post located in the through hole; and
a dielectric layer located in the through hole, wherein the conductive post is separated from the glass substrate by the dielectric layer.

2. The circuit substrate of claim 1, wherein the dielectric layer comprises:
a first dielectric portion located in the through hole to separate the conductive post and the glass substrate; and
a second dielectric portion covering a top surface of the first dielectric portion and a top surface of the glass substrate.

3. The circuit substrate of claim 2, wherein a height of the conductive post is greater than a thickness of the glass substrate.

4. The circuit substrate of claim 2, further comprising:
a surface conductive layer covering a top surface of the conductive post, wherein a top surface of the surface conductive layer is flush with a top surface of the second dielectric portion.

5. The circuit substrate of claim 1, wherein the conductive post has a top end and a bottom end, and a width of the top end is greater than a width of the bottom end.

6. The circuit substrate of claim 1, wherein the dielectric layer comprises a first dielectric portion, and the first dielectric portion is located in the through hole to separate the conductive post and the glass substrate.

7. The circuit substrate of claim 6, wherein a top surface of the conductive post is flush with a top surface of the glass substrate and a top surface of the first dielectric portion, and a height of the conductive post is equal to a thickness of the glass substrate.

8. The circuit substrate of claim 6, wherein the dielectric layer further comprises a second dielectric portion, the second dielectric portion covers a top surface of the first dielectric portion and a top surface of the glass substrate, and a top surface of the second dielectric portion is higher than a top surface of the conductive post.

9. The circuit substrate of claim 8, further comprising a first surface conductive layer, wherein the first surface conductive layer is embedded in the second dielectric portion, the first surface conductive layer covers the top surface of the conductive post, and the first surface conductive layer is protruded from a top surface of the second dielectric portion.

10. The circuit substrate of claim 9, wherein the dielectric layer further comprises a third dielectric portion, and the third dielectric portion covers a bottom surface of the first dielectric portion and a bottom surface of the glass substrate.

11. The circuit substrate of claim 10, further comprising a second surface conductive layer, wherein the second surface conductive layer is embedded in the third dielectric portion, the second surface conductive layer covers a bottom surface of the conductive post, and the second surface conductive layer is protruded from a bottom surface of the third dielectric portion.

12. A method for fabricating a circuit substrate, comprising:
forming a through hole in a glass substrate, wherein the glass substrate has a crack located around the through hole;
forming a conductive layer in the through hole of the glass substrate to repair the crack; and
forming a first dielectric portion in the through hole of the glass substrate.

13. The method for fabricating the circuit substrate of claim 12, further comprising:
forming a first surface conductive layer, wherein the first surface conductive layer covers a top surface of the first dielectric portion and a top end of the conductive layer; and
forming a second dielectric portion on the top surface of the first dielectric portion and a top surface of the glass substrate.

14. The method for fabricating the circuit substrate of claim 13, further comprising:
forming a second surface conductive layer, wherein the second surface conductive layer covers a bottom surface of the first dielectric portion and a bottom end of the conductive layer; and
forming a third dielectric portion on a bottom surface of the glass substrate.
